(19) United States
(12) Patent Application Publication
(10) Pub. No.: US 2025/0151580 A1
(43) Pub. Date: May 8, 2025

(54) DISPLAY PANEL AND DISPLAY APPARATUS

(71) Applicants: Hefei Visionox Technology Co., Ltd., Hefei (CN); KunShan Go-Visionox Opto-Electronics Co., Ltd, Kunshan (CN)

(72) Inventors: Zhengkui DONG, Hefei (CN); Yiming XIAO, Hefei (CN); Liusong NI, Hefei (CN); Deng GAO, Hefei (CN); Zengqiang XIA, Hefei (CN); Bowen YANG, Hefei (CN); Jian WU, Hefei (CN); Yunjie LIU, Hefei (CN); Zhihui XIAO, Hefei (CN)

(73) Assignees: Hefei Visionox Technology Co., Ltd., Hefei (CN); KunShan Go-Visionox Opto-Electronics Co., Ltd, Kunshan (CN)

(21) Appl. No.: 18/742,129

(22) Filed: Jun. 13, 2024

(30) Foreign Application Priority Data
Nov. 8, 2023 (CN) 202311499823.9

(51) Int. Cl. H10K 59/80; H10K 59/12; H10K 59/122; H10K 71/16

(52) U.S. Cl. CPC H10K 59/873; H10K 59/1201; H10K 59/122; H10K 71/164

(57) ABSTRACT

A display panel includes an array substrate, a plurality of light-emitting units arranged on the array substrate, an isolation structure arranged on the array substrate and separating the plurality of light-emitting units, and an encapsulation layer. The encapsulation layer includes at least a first encapsulation layer, each of the at least a first encapsulation layer is arranged on a side of a corresponding light-emitting unit of the plurality of light-emitting units away from the array substrate. An orthographic projection of the light-emitting unit on the array substrate is located within an orthographic projection of a corresponding first encapsulation layer on the array substrate. At least a part of the first encapsulation layer beyond the corresponding light-emitting unit is located between the corresponding light-emitting unit and the isolation structure.

### CROSS REFERENCE TO RELATED APPLICATION

The present application claims priority to Chinese Patent Application No. 202311499823.9 filed on Nov. 8, 2023, which is incorporated herein by reference in its entirety.

### TECHNICAL FIELD

The present application relates to the technical field of display, and in particular to a display panel, a display apparatus, and a manufacturing method for a display panel.

### BACKGROUND

Flat display panels such as organic light emitting diode (OLED) panels and display panels using light emitting diode (LED) devices are widely used in various consumer electronic products such as mobile phones, TVs, personal digital assistants, digital cameras, notebook computers, and desktop computers due to advantages such as high image quality, power saving, a thin body, and a wide range of applications, becoming the mainstream in display apparatuses.

However, performance of an encapsulation layer of the display panel in the related art is insufficient, which easily causes leakage of an etching liquid, eventually causing damage to a light-emitting unit. Therefore, a new display panel is in urgent need.

### SUMMARY

Embodiments of the present application provide a display panel, a display apparatus, and a manufacturing method for a display panel.

In a first aspect, according to an embodiment of the present application, a display panel is provided, including an array substrate, a plurality of light-emitting units, an isolation structure, and an encapsulation layer, wherein the plurality of light-emitting units are arranged on the array substrate, the isolation structure is arranged on the array substrate and separates the plurality of light-emitting units, the encapsulation layer includes at least a first encapsulation layer, each of the at least a first encapsulation layer is arranged on a side of a corresponding light-emitting unit of the plurality of light-emitting units away from the array substrate, an orthographic projection of the light-emitting unit on the array substrate is located within an orthographic projection of a corresponding first encapsulation layer on the array substrate, and at least a part of the first encapsulation layer beyond the corresponding light-emitting unit is located between the corresponding light-emitting unit and the isolation structure.

In a second aspect, according to an embodiment of the present application, a display panel is provided, including an array substrate, a plurality of light-emitting units, an isolation structure, and an encapsulation layer, wherein the plurality of light-emitting units are arranged on the array substrate; the isolation structure is arranged on the array substrate and separates the plurality of light-emitting units, the isolation structure includes a first isolation portion and a second isolation portion sequentially stacked in a direction close to the array substrate, and an orthographic projection of the second isolation portion on the array substrate is located within an orthographic projection of the first isolation portion on the array substrate; and the encapsulation layer includes at least a first encapsulation layer, each of the at least a first encapsulation layer is arranged on a side of a corresponding light-emitting unit of the plurality of light-emitting units away from the array substrate, and an orthographic projection of the light-emitting unit on the array substrate is located within an orthographic projection of a corresponding first encapsulation layer on the array substrate; wherein the first encapsulation layer includes a first portion located below the first isolation portion, and the first portion of the first encapsulation layer is not in contact with the first isolation portion.

In a third aspect, according to an embodiment of the present application, a display apparatus is provided, including the display panel as described above.

### BRIEF DESCRIPTION OF THE DRAWINGS

Features, advantages, and technical effects of exemplary embodiments of the present application will be described below with reference to the accompanying drawings.

FIG. 1 is a schematic plan view of a display panel according to an embodiment of the present application;

FIG. 2 is a schematic structural diagram of a display panel according to an embodiment of the present application;

FIG. 3 is a schematic structural diagram of another display panel according to an embodiment of the present application;

FIG. 4 is a schematic structural diagram of yet another display panel according to an embodiment of the present application;

FIG. 5 is a schematic structural diagram of yet another display panel according to an embodiment of the present application;

FIG. 6 is a schematic structural diagram of yet another display panel according to an embodiment of the present application;

FIG. 7 is a schematic structural diagram of yet another display panel according to an embodiment of the present application;

FIG. 8 is a schematic structural diagram of yet another display panel according to an embodiment of the present application;

FIG. 9 is a schematic structural diagram of yet another display panel according to an embodiment of the present application;

FIG. 10 is a schematic structural diagram of yet another display panel according to an embodiment of the present application;

FIG. 11 is a flowchart of manufacturing of a display panel according to an embodiment of the present application;

FIG. 12 is a flowchart of manufacturing of a display panel according to an embodiment of the present application;

FIG. 13 is a flowchart of manufacturing of a display panel according to an embodiment of the present application;

FIG. 14 is a flowchart of manufacturing of a display panel according to an embodiment of the present application;

FIG. 15 is a flowchart of manufacturing of a display panel according to an embodiment of the present application; and

FIG. 16 is a flowchart of manufacturing of a display panel according to an embodiment of the present application.

### REFERENCE SIGNS

1: display apparatus; 100: display panel; 10: base; 20: array layer; 30: light-emitting unit; 40: isolation structure; 50: first encapsulation layer; 60: pixel defining layer; 61: pixel opening;
31: first electrode; 32: light-emitting functional layer; 33: second electrode;
41: first isolation portion; 42: second isolation portion; 43: third isolation portion;
51: second encapsulation layer; 52: third encapsulation layer; 70: photoresist.

In the drawings, same components are denoted by same reference numerals. The drawings are not drawn to actual scale.

### DETAILED DESCRIPTION

Features and exemplary embodiments in various aspects of the present application will be described in detail below. In the following detailed description, numerous specific details are set forth in order to provide a thorough understanding of the present application. However, it will be apparent to those skilled in the art that the present application can be implemented without some of these specific details. The following description of the embodiments is merely to provide a better understanding of the present application by illustrating the examples of the present application. In the drawings and the following description, at least part of well-known structures and technologies are not shown in order to avoid unnecessarily obscuring the present application. Further, for clarity, the size of part of the structure may be exaggerated. Furthermore, the features, structures, or characteristics described below may be combined in any suitable manner in one or more embodiments.

The terms denoting directions that appear in the following description indicate directions shown in the drawings, and do not limit specific structures of the display panel, the display apparatus, and the manufacturing method for a display panel in the present application. In the description of the present application, it is to be further noted that unless specifically stated and limited, the terms “mount” and “connect” should be understood in a broad sense, such as, a fixed connection, a detachable connection, or an integral connection; or a direct connection, or an indirect connection. For those of ordinary skill in the art, the specific meanings of the above terms in embodiments of the present application may be understood depending on specific situations.

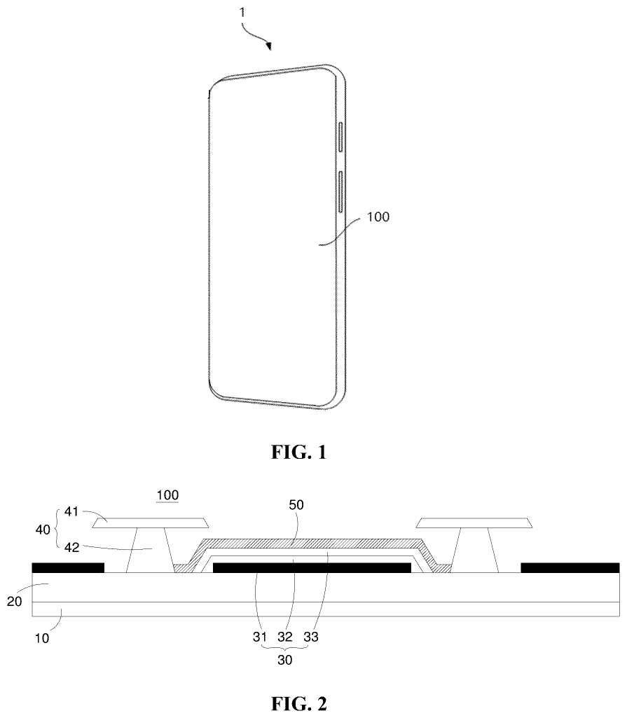

For a better understanding of the present application, a display panel, a display apparatus, and a manufacturing method for a display panel according to embodiments of the present disclosure will be described in detail below with reference to FIG. 1 to FIG. 16.

Referring to FIG. 1 and FIG. 2, an embodiment of the present application provides a display panel 100, including an array substrate, a plurality of light-emitting units 30, an isolation structure 40, and at least a first encapsulation layer 50. The array substrate includes a base 10 and an array layer 20 that are stacked. The array layer 20 is arranged on the base 10. The plurality of light-emitting units 30 are arranged on a side of the array layer 20 away from the base 10. The plurality of light-emitting units 30 are arranged at an interval. The isolation structure 40 is arranged on the side of the array layer 20 away from the base 10. The isolation structure 40 is arranged between adjacent light-emitting units 30. Each of the at least a first encapsulation layer 50 is arranged on a side of a corresponding light-emitting unit 30 away from the array layer 20. An orthographic projection of the light-emitting unit 30 on the base 10 is located within an orthographic projection of a corresponding first encapsulation layer 50 on the base 10. At least a part of the first encapsulation layer 50 beyond the corresponding light-emitting unit 30 overlaps between the corresponding light-emitting unit 30 and the isolation structure 40.

In the above implementation, the base 10 may be a rigid base 10 or a flexible base 10, the array layer 20 is also a driving circuit layer, which includes a plurality of driving circuits, each driving circuit includes a driving device, a signal line, and the like, and the driving device includes a transistor, a capacitor, and the like, which are not particularly limited in the present application.

It may be understood that the light-emitting units 30 may be arranged in an array on the display panel 100. The light-emitting units 30 may be red subpixels, green subpixels, and blue subpixels, after emission of red, green, and blue (RGB) light in three colors, color display is formed.

Each light-emitting unit 30 may include a first electrode 31, a light-emitting functional layer 32, and a second electrode 33. Preferably, the first electrode 31 is an anode, the second electrode 33 is a cathode, and the light-emitting functional layer 32 may use organic light-emitting materials to form light in different colors. The first electrode 31 injects and transports holes into the middle light-emitting functional layer 32 and the second electrode 33 injects and transports electrons into the light-emitting functional layer 32. The holes and the electrons are combined to form excitons in the light-emitting functional layer 32, causing the organic light-emitting materials to emit light to obtain the light in different colors.

Specifically, the first electrode 31 is arranged on the array layer 20, the light-emitting functional layer 32 is arranged on a side of the first electrode 31 away from the array layer 20, and the second electrode 33 is arranged on a side of the light-emitting functional layer 32 away from the first electrode 31. Specifically, the first electrode 31 is formed on a side of the array layer 20 away from the base 10 and is electrically connected to the driving circuit in the array layer 20.

In the above implementation, with the arrangement of the isolation structure 40, the light-emitting units 30 in different colors may be manufactured separately and independently of each other. Specifically, continuous arrangement of the light-emitting functional layers 32 between adjacent light-emitting units 30 may cause lateral crosstalk, causing the adjacent light-emitting units 30 to emit light by mistake or the like, which affects display quality. After the light-emitting units 30 are arranged independently of each other, the problem of lateral crosstalk between adjacent light-emitting units 30 can be alleviated, and the display quality of the display panel 100 can be improved.

Since the isolation structure 40 is arranged on the array layer 20, when the light-emitting functional layer 32 and the second electrode 33 are evaporated, the light-emitting functional layer 32 forms isolation at the isolation structure 40 to make adjacent light-emitting units 30 independent of each other, thereby preventing crosstalk. Optionally, the second electrode 33 can overlap with the isolation structure 40 so that the second electrode 33 forms a whole-layer structure. Certainly, the second electrode 33 may not overlap with the isolation structure 40 so that the second electrodes 33 are independent of each other.

When the display panel 100 includes the isolation structure 40, the light-emitting units 30 in each color may be manufactured in a whole layer and then patterned, thereby omitting the use of a mask and reducing costs. The light-emitting units 30 in different colors are manufactured in different orders. During patterning of the light-emitting units 30 manufactured later, isolation may be implemented by the isolation structure 40 to improve a yield of the patterning process and reduce an impact of the patterning on a yield of the light-emitting units 30.

Optionally, the isolation structure 40 has a columnar structure. A function of the isolation structure 40 in this embodiment is to isolate the second electrode 33 from the light-emitting functional layer 32, thereby eliminating a fine mask and preventing crosstalk between adjacent colored lights.

Optionally, a cross section of the isolation structure 40 along a thickness direction of the display panel 100 is in a shape of a regular trapezoid or an inverted trapezoid, which may be patterned according to a specific deposition and etching process. The isolation structure 40 may be a composite metal titanium-aluminum-titanium (Ti/Al/Ti) structure or a titanium-aluminum-molybdenum (Ti/Al/Mo) structure, or may be made of an insulating material. The specific shape and material of the isolation structure 40 are not specially limited in the present application.

The first encapsulation layer 50 is arranged on the second electrode 33 of the corresponding light-emitting unit 30. The first encapsulation layer 50 can form isolation protection for the second electrode 33 and the light-emitting functional layer 32 to prevent adverse effects caused by entry of water vapor in an external environment into a screen.

In consideration of overall light transmittance of the display panel 100, the first encapsulation layer 50 is required to be a light-transmitting film layer, which may be an inorganic material layer, and a specific material may be silicon nitride or other materials. The first encapsulation layer 50 is deposited on the second electrode 33 through a chemical vapor deposition (CVD) process, thereby forming protection.

In this embodiment, in consideration of insufficient encapsulation performance of the first encapsulation layer 50, the orthographic projection of the light-emitting unit 30 on the base 10 is located within the orthographic projection of the first encapsulation layer 50 to form full coverage of the light-emitting unit 30 by the first encapsulation layer 50, and at the same time, an excess portion of the first encapsulation layer 50 overlaps between the light-emitting unit 30 and the isolation structure 40, which prevents poor overlapping of encapsulation caused by formation of a gap due to overlapping of the first encapsulation layer 50 with a side wall of the isolation structure 40 and causes the excess portion of the first encapsulation layer 50 to form sufficient overlapping with the film layer below it.

Optionally, adjacent first encapsulation layers 50 are arranged at an interval, each light-emitting unit 30 is provided with a corresponding first encapsulation layer 50, and the first encapsulation layer 50 is an independent encapsulation structure arranged corresponding to each light-emitting unit 30. Adjacent light-emitting units 30 are arranged at an interval under the action of the isolation structure 40, and corresponding first encapsulation layers 50 of the adjacent light-emitting units 30 also form isolation at the isolation structure 40, so that the adjacent first encapsulation layers 50 are not in contact, and the first encapsulation layer 50 has a discontinuous encapsulation structure.

The position of the film layer with which the first encapsulation layer 50 fully overlaps is not specially limited in the present application, as long as the first encapsulation layer 50 can be ensured to form sufficient contact with the film layer below it in an overlap manner to prevent occurrence of an encapsulation gap.

An embodiment of the present application provides a display panel 100. The first encapsulation layer 50 is arranged on the light-emitting unit 30, so that the first encapsulation layer 50 fully covers the light-emitting unit 30. An edge of the first encapsulation layer 50 beyond the light-emitting unit 30 is fully overlapped between the light-emitting unit 30 and the isolation structure 40, so that the first encapsulation layer 50 and a film layer below it are fully overlapped, thereby preventing a gap formed between the first encapsulation layer 50 and the overlapping film layer, which prevents subsequent damage to the light-emitting unit 30 due to entry of an etching liquid into the light-emitting unit 30 through the gap, improves encapsulation performance of the first encapsulation layer 50, improves an encapsulation capability of the first encapsulation layer 50, forms better encapsulation protection for the light-emitting unit 30, improves safety performance of the light-emitting unit 30, and provides a reliable guarantee for stable light emission of the entire display panel 100.

As an optional embodiment, the light-emitting unit 30 includes a first electrode 31, a light-emitting functional layer 32, and a second electrode 33 that are sequentially stacked, the second electrode 33 is located on a side of the light-emitting functional layer 32 away from the first electrode 31, the first encapsulation layer 50 covers the second electrode 33 of the corresponding light-emitting unit 30, and at least a part of the first encapsulation layer 50 beyond the second electrode 33 of the corresponding light-emitting unit 30 overlaps with a side of the array layer 20 away from the base 10.

Optionally, the first encapsulation layer 50 is specifically deposited on the second electrode 33, and the first encapsulation layer 50, after being formed, may overlap with any film layer on the array layer 20 to form sufficient and reliable overlapping with the film layer, which prevents poor encapsulation caused by the formation of encapsulation only by overlapping with the side wall of the isolation structure 40.

An embodiment of the present application provides a display panel 100. A portion of the first encapsulation layer 50 beyond the light-emitting unit 30 overlaps with the array layer 20, providing a variety of overlapping positions with different thicknesses for the first encapsulation layer 50, forming more sufficient overlapping, and providing more possibilities for reliable encapsulation effects.

As an optional embodiment, referring to FIG. 2, the isolation structure 40 is directly arranged on the array layer 20 and is spaced from the light-emitting unit 30, the first encapsulation layer 50 covers the second electrode 33, and at least a part of the first encapsulation layer 50 beyond the second electrode 33 overlaps with the array layer 20.

In this embodiment, the isolation structure 40 is directly arranged on the array layer 20, an isolation function of the isolation structure 40 is used to define different light-emitting units 30, adjacent light-emitting units 30 are spaced from each other through the isolation structure 40 and do not interfere with each other, the second electrodes 33 of the adjacent light-emitting units 30 are independent of each other, and each second electrode 33 may be provided with cathode potential separately to conduct a cathode signal.

In this case, the light-emitting unit 30 is encapsulated with the part of the first encapsulation layer 50 beyond the light-emitting unit 30 directly overlapping with the array layer 20. The overlapping portion between the first encapsulation layer 50 and the array layer 20 is used to form reliable encapsulation for the light-emitting unit 30 and form safe protection for the light-emitting unit 30.

An embodiment of the present application provides a display panel 100, wherein an isolation structure 40 is used to define a plurality of light-emitting units 30 and isolate adjacent light-emitting units 30 to prevent crosstalk. At the same time, the first encapsulation layer 50 directly overlaps with the array layer 20 to form sufficient contact therebetween to form reliable overlapping, which provides better encapsulation protection for the light-emitting unit 30 and achieves a better encapsulation effect.

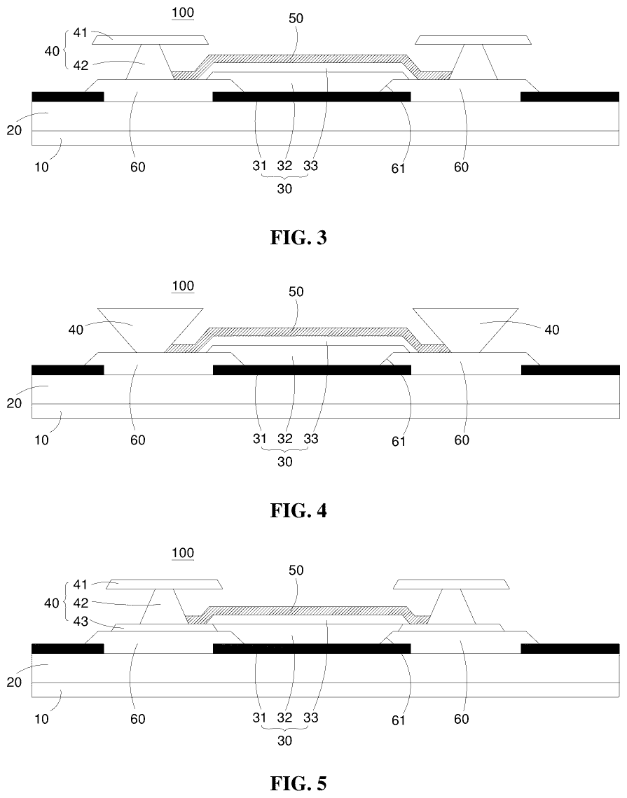

As an optional embodiment, referring to FIG. 3, the display panel 100 includes a plurality of pixel defining layers 60 arranged on the array layer 20, adjacent pixel defining layers of the plurality of pixel defining layers 60 enclose a pixel opening 61, the light-emitting unit 30 is arranged in the pixel opening 61, the isolation structure 40 is arranged on a side of the pixel defining layer 60 away from the array layer 20 and is spaced from the light-emitting unit 30, the first encapsulation layer 50 covers the second electrode 33, and the at least a part of the first encapsulation layer 50 beyond the second electrode 33 overlaps with the pixel defining layer 60.

Optionally, the display panel 100 further includes a plurality of pixel defining layers 60 and a plurality of pixel openings 61 enclosed by the plurality of pixel defining layers 60, the pixel defining layers 60 forms the pixel openings 61, the light-emitting unit 30 is arranged in the pixel opening 61, and the pixel opening 61 is arranged corresponding to the first electrode 31.

Optionally, the isolation structure 40 is provided with a plurality of isolation openings corresponding to the plurality of pixel openings 61, each of the plurality of isolation openings is in communication with a corresponding pixel opening of the plurality of pixel opening 61.

Specifically, the pixel defining layer 60 is deposited on the first electrode 31, the pixel opening 61 is formed by etching a corresponding position of the first electrode 31 so that a part of the first electrode 31 is exposed in the pixel opening 61, the pixel defining layer 60 only covers an edge of the first electrode 31, and the light-emitting functional layer 32 is deposited in the pixel opening 61 to form a connection with the first electrode 31. After formed by etching, the pixel defining layer 60 covers the edge of the first electrode 31 to form isolation protection for the first electrode 31 to prevent an influence of an external water oxygen environment. Then, the second electrode 33 is deposited on the light-emitting functional layer 32 to form the light-emitting unit 30 as a whole.

In this embodiment, the isolation structure 40 is arranged on the pixel defining layer 60 and isolates adjacent light-emitting units 30. In this case, the second electrode 33 of each light-emitting unit 30 is disconnected at the isolation structure 40, and also serves as an independent structure. Cathode potential may be provided separately for the second electrode 33 to achieve conduction of a cathode signal.

When the second electrode 33 is encapsulated by using the first encapsulation layer 50, in order to fully cover the light-emitting unit 30, the first encapsulation layer 50 may be directly overlapped with the pixel defining layer 60 between the light-emitting unit 30 and the isolation structure 40, so that the first encapsulation layer 50 is in direct contact with the pixel defining layer 60 to encapsulate the light-emitting unit 30.

Optionally, as shown in FIG. 4, the isolation structure 40 may be an integrally formed structure and has a first surface away from the array substrate and a second surface close to the array substrate, and in a cross section perpendicular to the array substrate, a size of the first surface is larger than that of the second surface. In other words, the isolation structure 40 forms an inverted trapezoidal structure on the above cross section.

During the evaporation and forming process of the light-emitting functional layer 32, the inverted trapezoidal structure of the isolation structure 40 can also isolate the light-emitting functional layer 32, and the relatively long first surface thereof is used to isolate the light-emitting functional layer 32 to prevent crosstalk between adjacent light-emitting units 30. In this case, under the action of the isolation structure 40, the second electrode 33 is not required to overlap with the isolation structure 40 due to an isolation effect of the first surface. Each second electrode 33 may be provided with VSS cathode potential through an independent metal structure. After deposition, the first encapsulation layer 50 overlaps with the pixel defining layer 60 between the second electrode 33 and the isolation structure 40, thereby forming stable and reliable overlapping to provide better encapsulation protection for the light-emitting unit 30.

An embodiment of the present application provides a display panel 100, wherein pixel defining layers 60 are arranged in the panel 100, the pixel defining layers 60 enclose pixel openings 61, the isolation structure 40 is arranged on the pixel defining layer 60, and the first encapsulation layer 50 can better encapsulate the light-emitting unit 30 by directly contacting the pixel defining layer 60, thereby achieving a better encapsulation effect, improving safety performance of the light-emitting unit 30, and preventing entry of an etching liquid.

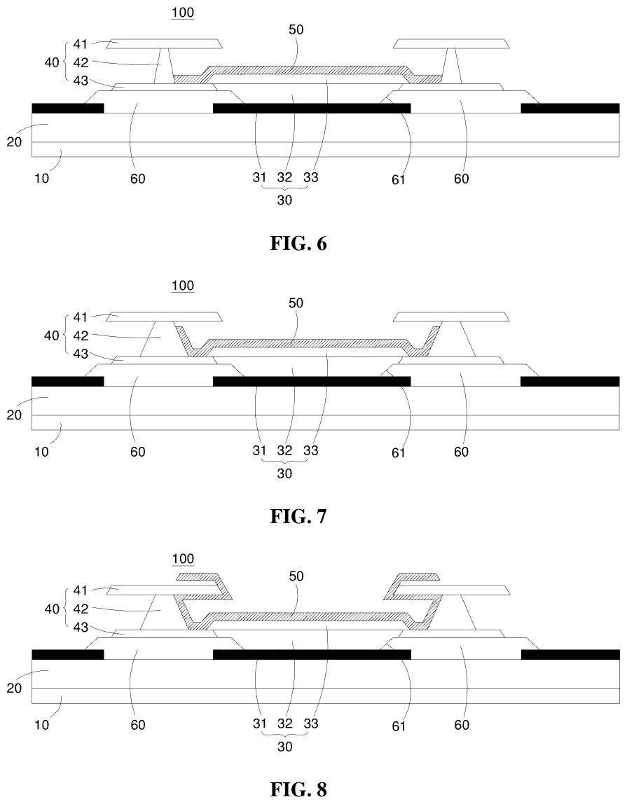

As an optional embodiment, referring to FIG. 5 and FIG. 6, the isolation structure 40 includes a first isolation portion 41, a second isolation portion 42, and a third isolation portion 43 that are stacked, the second isolation portion 42 is located between the first isolation portion 41 and the third isolation portion 43, the third isolation portion 43 is arranged on the array layer 20, an orthographic projection of the second isolation portion 42 on the base 10 is located within orthographic projections of the first isolation portion 41 and the third isolation portion 43 on the base 10, the second electrode 33 overlaps with the third isolation portion 43, the first encapsulation layer 50 covers the second electrode 33, and at least a part of the first encapsulation layer 50 beyond the second electrode 33 overlaps with the third isolation portion 43.

Optionally, the isolation structure 40 has a three-layer composite structure, the second isolation portion 42 is arranged between the first isolation portion 41 and the third isolation portion 43 and has a length dimension less than those of the first isolation portion 41 and the third isolation portion 43, and the isolation structure 40 isolates evaporation of the light-emitting functional layer 32 and the second electrode 33 through the first isolation portion 41 to separate adjacent light-emitting units 30 and prevent mutual crosstalk.

Optionally, the first isolation portion 41 may be made of metal titanium, the second isolation portion 42 may be made of metal aluminum, and the third isolation portion 43 may be made of metal molybdenum. In this embodiment, the second electrode 33 in each light-emitting unit 30 overlaps with the adjacent isolation structure 40, conductive properties of the isolation structure 40 are used to connect the second electrodes 33 of adjacent light-emitting units 30 so that the second electrodes 33 form a continuous whole-layer structure, which can provide cathode potential and conduction for the second electrodes 33 of the whole layer.

Specifically, each second electrode 33 is overlapped with the third isolation portion 43 of the isolation structure 40 to achieve conduction between adjacent second electrodes 33. When the first encapsulation layer 50 is used for encapsulation, the first encapsulation layer 50 fully covers the light-emitting unit 30 and forms direct contact with the third isolation portion 43, thereby achieving sufficient overlapping of the first encapsulation layer 50 and ensuring an encapsulation effect of the first encapsulation layer 50.

An embodiment of the present application provides a display panel 100, wherein mainly in consideration of poor encapsulation caused by a gap formed between the first encapsulation layer 50 and a side wall of the second isolation portion 42 in the case of the first encapsulation layer 50 overlapping with the second isolation portion 42, in this embodiment, the first encapsulation layer 50 overlaps with the third isolation portion 43, and the first encapsulation layer 50 and the third isolation portion 43 are in direct contact, thereby improving an encapsulation effect. On the basis of using the third isolation portion 43 to conduct the second electrode 33, a reliable overlapping position can be provided for the first encapsulation layer 50, and performance of the first encapsulation layer 50 can be improved.

As an optional embodiment, referring to FIG. 7, one part of the first encapsulation layer 50 beyond the second electrode 33 overlaps with the third isolation portion 43, and the other part of the first encapsulation layer 50 beyond the second electrode 33 overlaps with a side wall of the second isolation portion 42.

In consideration of an actual deposition process, one part of the first encapsulation layer 50 covers the light-emitting unit 30 and overlaps with the third isolation portion 43, and at the same time, another part of the first encapsulation layer 50 is evaporated onto the side wall of the second isolation portion 42 and also forms direct contact with the second isolation portion 42.

Optionally, the first encapsulation layer 50 is located below the first isolation portion 41 and is not in contact with the first isolation portion 41, and an orthographic projection of a part of the first encapsulation layer 50 on the array substrate is located outside the orthographic projection of the first isolation portion 41 on the array substrate.

In other words, after evaporation, the first encapsulation layer 50 is not required to climb along the side wall of the second isolation portion 42 to the first isolation portion 41, but only overlaps with the side wall of the second isolation portion 42 of the isolation structure 40 and the third isolation portion 43. The part overlapping with the third isolation portion 43 mainly produces a reliable encapsulation effect.

Referring to FIG. 8, optionally, the first encapsulation layer 50 extends from the side wall of the second isolation portion 42 to cover the first isolation portion 41, and a part of the first encapsulation layer 50 overlaps with the first isolation portion 41 and is located on a side of the first isolation portion 41 away from the second isolation portion 42.

Since the first encapsulation layer 50 is partially blocked by the first isolation portion 41 during the deposition, in order to achieve a more reliable encapsulation effect, the first encapsulation layer 50 may continuously climb along the side wall of the second isolation portion 42 to the first isolation portion 41, the first encapsulation layer 50 covers a part of a bottom surface of the first isolation portion 41 and is deposited to a top surface of the first isolation portion 41, so that more sufficient overlapping is formed between the first encapsulation layer 50 and the isolation structure 40 and there is a larger contact area therebetween. At the same time, the structure is also more consistent with an actual structure after deposition of the first encapsulation layer 50.

An embodiment of the present application provides a display panel 100, wherein the first encapsulation layer 50 is arranged on the second isolation portion 42 and the third isolation portion 43, which increases a contact area between the first encapsulation layer 50 and the isolation structure 40, further achieves full coverage of the light-emitting unit 30, improves an overall encapsulation effect, and has a better encapsulation capability.

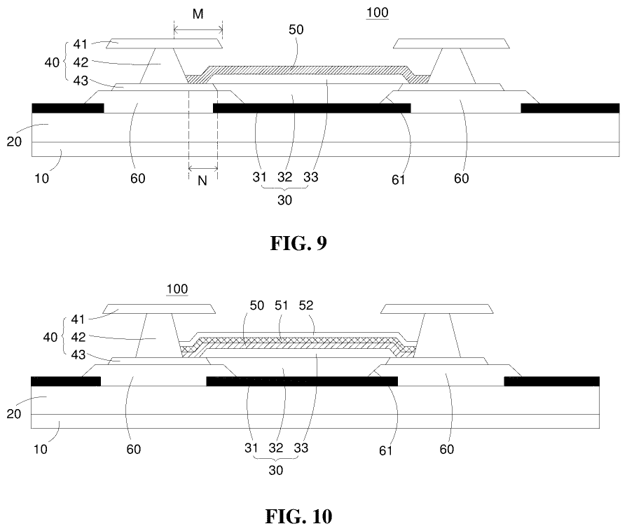

As an optional embodiment, referring to FIG. 9, in a cross section of the display panel along a thickness direction thereof, a height of the second isolation portion 42 is in a range from 0.4 μm to 1.2 μm; a ratio of a length M of the first isolation portion 41 beyond the second isolation portion 42 to the height of the second isolation portion 42 is in a range from 1.5 to 3.0; and a length N of the third isolation portion 43 beyond the second isolation portion 42 is in a range from 0.4 μm to 3.0 μm.

An embodiment of the present application provides a display panel 100, by controlling the length dimension of the first isolation portion 41, a deposition effect of the first encapsulation layer 50 is ensured while evaporation partition is formed for the light-emitting functional layer 32 and the second electrode 33, so that the first encapsulation layer 50 forms more sufficient coverage of the light-emitting unit 30. At the same time, by appropriately reducing the length dimension of the second isolation portion 42 and increasing the length of the third isolation portion 43 beyond the second isolation portion 42, the first encapsulation layer 50 can form more sufficient contact with the third isolation portion 43, thereby increasing a contact area therebetween, having better overlapping stability, and improving the encapsulation capability of the first encapsulation layer 50.

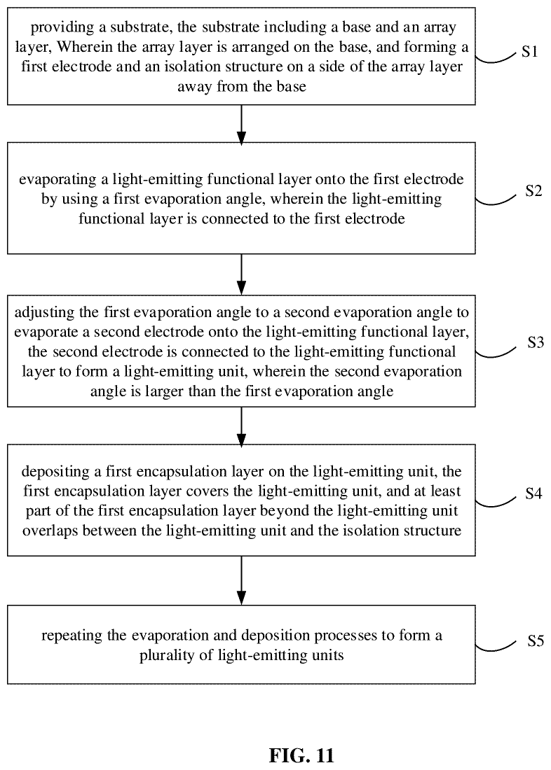

As an optional embodiment, referring to FIG. 10, the encapsulation layer includes a second encapsulation layer 51 and a third encapsulation layer 52 that are stacked with the first encapsulation layer 50, the first encapsulation layer 50 covers the corresponding light-emitting unit 30 and the second encapsulation layer 51 is arranged between the first encapsulation layer 50 and the third encapsulation layer 52, and at least a part of the first encapsulation layer 50 beyond the corresponding light-emitting unit 30 and located between the corresponding light-emitting unit 30 and the isolation structure 40 overlaps with a side of the array substrate close to the light-emitting unit 30.

Optionally, the encapsulation layer may have a three-layer stacked structure, and the first encapsulation layer 50, the second encapsulation layer 51, and the third encapsulation layer 52 are sequentially stacked on the light-emitting unit 30. The first encapsulation layer 50 and the third encapsulation layer 52 may be made of inorganic materials and formed by a CVD process. The second encapsulation layer 51 may be made of organic materials and formed by inkjet printing. The specific structure of the encapsulation layer is not specially limited in the present application, as along as the encapsulation effect can be achieved.

An embodiment of the present application provides a display panel 100, wherein the encapsulation layer is arranged into a three-layer stacked structure, which further improves encapsulation performance of the encapsulation layer, forms better encapsulation protection for the light-emitting unit 30, and improves overall safety performance.

An embodiment of the present application further provides a display panel 100, including an array substrate, a plurality of light-emitting units 30, an isolation structure 40, and an encapsulation layer. The plurality of light-emitting units 30 are arranged on the array substrate. The isolation structure 40 is arranged on the array substrate and separates the plurality of light-emitting units 30, the isolation structure 40 includes a first isolation portion 41 and a second isolation portion 42 sequentially stacked in a direction close to the array substrate, and an orthographic projection of the second isolation portion 42 on the array substrate is located within an orthographic projection of the first isolation portion 41 on the array substrate. The encapsulation layer includes at least a first encapsulation layer 50 arranged on a side of a corresponding light-emitting unit of the plurality of light-emitting units 30 away from the array substrate, and an orthographic projection of the light-emitting unit 30 on the array substrate is located within an orthographic projection of a corresponding first encapsulation layer 50 on the array substrate. The first encapsulation layer 50 includes a first portion located below the first isolation portion 41, and the first portion of the first encapsulation layer 50 is not in contact with the first isolation portion 41.

On the display panel provided in this embodiment, the first portion of the deposited first encapsulation layer 50 is located below the first isolation portion 41, and in this case, the first portion is not in contact with the first isolation portion 41, which is different from the existing structure, in the existing structure, the first encapsulation layer 50 overlaps with the side wall of the second isolation portion 42 and above the first isolation portion 41, it is easy to form gaps between the first encapsulation layer 50 and the first isolation portion 41 and between the first encapsulation layer 50 and the second isolation portion 42, causing the problem of poor encapsulation. Therefore, in this embodiment, the first portion of the first encapsulation layer 50 mainly forms reliable overlapping with the film layer below the first isolation portion 41 to form better encapsulation protection for the light-emitting unit 30.

On this basis, optionally, an orthographic projection of at least a part of the first portion of the first encapsulation layer 50 on the array substrate is located outside the orthographic projection of the first isolation portion 41 on the array substrate. In this case, the first portion of the first encapsulation layer 50 is deposited below the first isolation portion 41, and is blocked by the first isolation portion 41 during the deposition, so that the first portion of the first encapsulation layer 50 is spaced from the first isolation portion 40, which prevents poor encapsulation caused by formation of a gap when the first encapsulation layer 50 is affected by the isolation structure 40. A main objective of this embodiment is to use the first portion of the first encapsulation layer 50 to form reliable overlapping with the film layer between the isolation structure 40 and the light-emitting unit 30, which overcomes an influence of the above gap on the encapsulation and has a better encapsulation effect on the light-emitting unit 30.

An embodiment of the present application provides a display apparatus 1, including the display panel 100 as described above.

Referring to FIG. 11, an embodiment of the present application provides a manufacturing method for a display panel 100 is provided, including the following steps.

In S1, a substrate is provided, the substrate includes a base 10 and an array layer 20, the array layer 20 is arranged on the base 10, and a first electrode 31 and an isolation structure 40 are formed on a side of the array layer 20 away from the base 10.

In S2, a light-emitting functional layer 32 is evaporated onto the first electrode 31 by using a first evaporation angle, and the light-emitting functional layer 32 is connected to the first electrode 31.

In S3, the first evaporation angle is adjusted to a second evaporation angle to evaporate a second electrode 33 onto the light-emitting functional layer 32, and the second electrode 33 is connected to the light-emitting functional layer 32 to form a light-emitting unit 30, wherein the second evaporation angle is larger than the first evaporation angle.

In S4, a first encapsulation layer 50 is deposited on the light-emitting unit 30, the first encapsulation layer 50 covers the light-emitting unit 30, and at least a part of the first encapsulation layer 50 beyond the light-emitting unit 30 overlaps between the light-emitting unit 30 and the isolation structure 40.

In S5, the evaporation and deposition processes are repeated to form a plurality of light-emitting units 30.

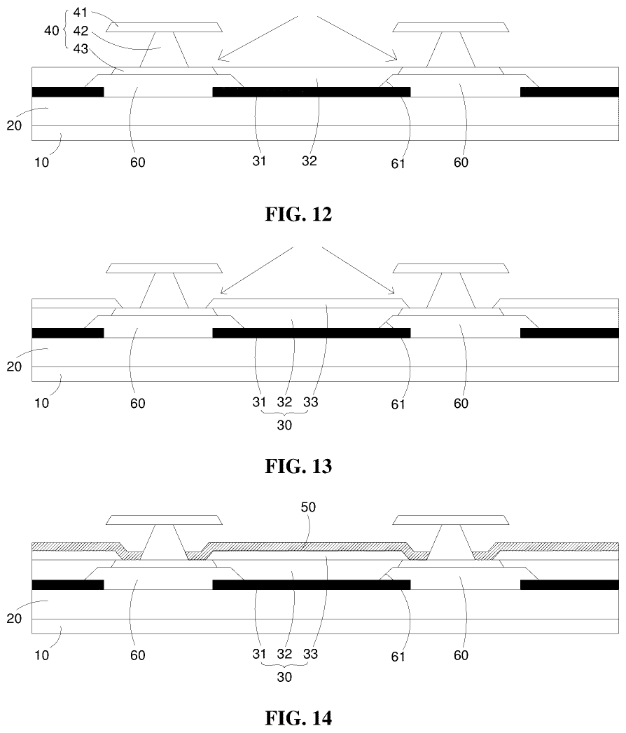

Referring to FIG. 12 and FIG. 13, in step S2 and step S3, the light-emitting functional layer 32 is evaporated by using the first evaporation angle and is connected to the first electrode 31, then the angle is increased to the second evaporation angle, and the second electrode 33 is evaporated by using the second evaporation angle, so that the second electrode 33 can completely cover the light-emitting functional layer 32 to form a connection, thereby finally forming a complete light-emitting unit 30.

In step S4, as shown in FIG. 14, the first encapsulation layer 50 is deposited on the second electrode 33 through a CVD process to form encapsulation protection for the entire light-emitting unit 30, and at least a part of the first encapsulation layer 50 is deposited between the light-emitting unit 30 and the isolation structure 40 to form overlapping, which has better encapsulation protection performance and prevents erosion and damage to the light-emitting unit 30 by the etching liquid in the subsequent step S5.

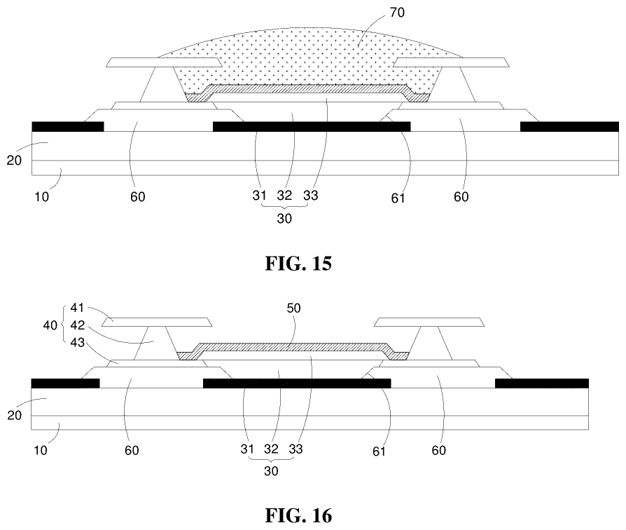

In step S5, as shown in FIG. 15 and FIG. 16, the first encapsulation layer 50 is further coated with photoresist 70, the display panel 100 is exposed and developed, a part of the film layer in the pixel opening 61 is removed by photolithography, then the remaining photoresist 70 is peeled off, and the above evaporation process is repeated, thereby forming light-emitting units 30 in different colors in adjacent pixel openings 61, meeting a variety of different display requirements, and obtaining the final display panel 100.

The embodiments of the present application provide a display panel, a display apparatus, and a manufacturing method for a display panel. The first encapsulation layer is arranged on the light-emitting unit, so that the first encapsulation layer fully covers the light-emitting unit. An edge of the first encapsulation layer beyond the light-emitting unit is fully overlapped between the light-emitting unit and the isolation structure, so that the first encapsulation layer and a film layer below the first encapsulation layer are sufficiently contacted in an overlap manner, thereby preventing a gap between the first encapsulation layer and the overlapping film layer, and preventing subsequent damage to the light-emitting unit due to entry of an etching liquid into the light-emitting unit through the gap, which improves encapsulation performance of the first encapsulation layer, improves an encapsulation capability of the first encapsulation layer, forms better encapsulation protection for the light-emitting unit, improves safety performance of the light-emitting unit, and provides a reliable guarantee for stable light emission of the entire display panel.

Although the present application has been described with reference to the preferred embodiments, various modifications may be made thereto and components may be replaced with equivalents without departing from the scope of the present application. In particular, the technical features mentioned in various embodiments can be combined in any manner provided that there is no structural conflict. The present application is not limited to the specific embodiments disclosed herein, but includes all technical solutions falling into the protection scope of the claims.

What is claimed is:

1. A display panel, comprising:
an array substrate;
a plurality of light-emitting units arranged on the array substrate;
an isolation structure arranged on the array substrate and separating the plurality of light-emitting units; and
an encapsulation layer comprising at least a first encapsulation layer, each of the at least a first encapsulation layer arranged on a side of a corresponding light-emitting unit of the plurality of light-emitting units away from the array substrate, an orthographic projection of the light-emitting unit on the array substrate being located within an orthographic projection of a corresponding first encapsulation layer on the array substrate, and at least a part of the first encapsulation layer beyond the corresponding light-emitting unit being located between the corresponding light-emitting unit and the isolation structure.

2. The display panel of claim 1, wherein the at least a first encapsulation layer comprises a plurality of first encapsulation layers, adjacent first encapsulation layers are arranged at an interval.

3. The display panel of claim 1, wherein the light-emitting unit comprises a first electrode, a light-emitting functional layer, and a second electrode sequentially stacked in a direction away from the array substrate, the first encapsulation layer covers the second electrode of the corresponding light-emitting unit, and at least a part of the first encapsulation layer beyond the second electrode of the corresponding light-emitting unit overlaps with a side of the array substrate close to the light-emitting unit.

4. The display panel of claim 3, wherein the isolation structure is in direct contact with the array substrate and is provided with a plurality of isolation openings to accommodate the light-emitting units, the at least a part of the first encapsulation layer beyond the second electrode directly overlaps with the array substrate.

5. The display panel of claim 3, wherein the display panel comprises a pixel defining layer arranged on the array substrate, the pixel defining layer is provided with a plurality of pixel openings, the light-emitting unit is arranged in the pixel opening, the isolation structure is arranged on a side of the pixel defining layer away from the array substrate, and the at least a part of the first encapsulation layer beyond the second electrode overlaps with the pixel defining layer;
the isolation structure is provided with a plurality of isolation openings corresponding to the plurality of pixel openings, each of the plurality of isolation openings is in communication with a corresponding pixel opening of the plurality of pixel openings;
the isolation structure is an integrally formed structure and has a first surface away from the array substrate and a second surface close to the array substrate, and in a cross section perpendicular to the array substrate, a size of the first surface is larger than that of the second surface; or
the isolation structure comprises a first isolation portion and a second isolation portion sequentially stacked in a direction close to the array substrate, the second isolation portion is in direct contact with the array substrate, and an orthographic projection of the second isolation portion on the array substrate is located within an orthographic projection of the first isolation portion on the array substrate.

6. The display panel of claim 3, wherein the isolation structure comprises a first isolation portion, a second isolation portion, and a third isolation portion sequentially stacked in a direction close to the array substrate, and the at least a part of the first encapsulation layer beyond the second electrode overlaps with the third isolation portion;
the third isolation portion is in direct contact with the array substrate, an orthographic projection of the second isolation portion on the array substrate is located within an orthographic projection of the first isolation portion on the array substrate and located within an orthographic projection of the third isolation portion on the array substrate, and the second electrode overlaps with the third isolation portion.

7. The display panel of claim 6, wherein one part of the first encapsulation layer beyond the second electrode overlaps with the third isolation portion, and the other part of the first encapsulation layer beyond the second electrode overlaps with a side wall of the second isolation portion;
the first encapsulation layer is located below the first isolation portion and is not in contact with the first isolation portion, and an orthographic projection of a part of the first encapsulation layer on the array substrate is located outside the orthographic projection of the first isolation portion on the array substrate; or
the first encapsulation layer extends from the side wall of the second isolation portion to cover the first isolation portion, and a part of the first encapsulation layer overlaps with the first isolation portion and is located on a side of the first isolation portion away from the second isolation portion.

8. The display panel of claim 6, wherein in a cross section of the display panel along a thickness direction thereof, a height of the second isolation portion is in a range from 0.4 μm to 1.2 μm;
in the cross section of the display panel along the thickness direction thereof, a ratio of a length of the first isolation portion beyond the second isolation portion to the height of the second isolation portion is in a range from 1.5 to 3.0; and
in a cross section of the display panel along a thickness direction thereof, a length of the third isolation portion beyond the second isolation portion is in a range from 0.4 μm to 3.0 μm.

9. The display panel of claim 1, wherein the encapsulation layer comprises a second encapsulation layer and a third encapsulation layer that are stacked with the first encapsulation layer, the first encapsulation layer covers the corresponding light-emitting unit and the second encapsulation layer is arranged between the first encapsulation layer and the third encapsulation layer, and at least a part of the first encapsulation layer beyond the corresponding light-emitting unit and located between the corresponding light-emitting unit and the isolation structure overlaps with a side of the array substrate close to the light-emitting unit.

10. A display panel, comprising:
an array substrate;
a plurality of light-emitting units arranged on the array substrate;
an isolation structure arranged on the array substrate and separating the plurality of light-emitting units, the isolation structure comprising a first isolation portion and a second isolation portion sequentially stacked in a direction close to the array substrate, and an orthographic projection of the second isolation portion on the array substrate being located within an orthographic projection of the first isolation portion on the array substrate; and
an encapsulation layer comprising at least a first encapsulation layer, each of the at least a first encapsulation layer arranged on a side of a corresponding light-emitting unit of the plurality of light-emitting units away from the array substrate, an orthographic projection of the light-emitting unit on the array substrate being located within an orthographic projection of a corresponding first encapsulation layer on the array substrate;
wherein the first encapsulation layer comprises a first portion located below the first isolation portion, and the first portion of the first encapsulation layer is not in contact with the first isolation portion.

11. The display panel of claim 10, wherein an orthographic projection of at least a part of the first portion of the first encapsulation layer on the array substrate is located outside the orthographic projection of the first isolation portion on the array substrate.

12. The display panel of claim 10, wherein the first portion of the first encapsulation layer overlaps with the array substrate between the isolation structure and the light-emitting unit.

13. The display panel of claim 10, wherein the at least a first encapsulation layer comprises a plurality of first encapsulation layers, adjacent first encapsulation layers are arranged at an interval.

14. The display panel of claim 10, wherein the light-emitting unit comprises a first electrode, a light-emitting functional layer, and a second electrode sequentially stacked in a direction away from the array substrate, the first encapsulation layer covers the second electrode of the corresponding light-emitting unit, and at least a part of the first encapsulation layer beyond the second electrode overlaps with a side of the array substrate close to the light-emitting unit.

15. The display panel of claim 14, wherein the isolation structure is in direct contact with the array substrate and is provided with a plurality of isolation openings to accommodate the light-emitting units, and the at least a part of the first encapsulation layer beyond the second electrode directly overlaps with the array substrate.

16. The display panel of claim 14, wherein the display panel comprises a pixel defining layer arranged on the array substrate, the pixel defining layer is provided with a plurality of pixel openings, the light-emitting unit is arranged in the pixel opening, the isolation structure is arranged on a side of the pixel defining layer away from the array substrate, and the at least a part of the first encapsulation layer beyond the second electrode overlaps with the pixel defining layer;
the isolation structure is provided with a plurality of isolation openings corresponding to the plurality of pixel openings, each of the plurality of isolation openings is in communication with a corresponding pixel opening of the plurality of pixel openings.

17. The display panel of claim 14, wherein the isolation structure comprises a first isolation portion, a second isolation portion, and a third isolation portion sequentially stacked in a direction close to the array substrate, and the at least a part of the first encapsulation layer beyond the second electrode overlaps with the third isolation portion; and
the third isolation portion is in direct contact with the array substrate, an orthographic projection of the second isolation portion on the array substrate is located within an orthographic projection of the first isolation portion on the array substrate and located within an orthographic projection of the third isolation portion on the array substrate, and the second electrode overlaps with the third isolation portion.

18. The display panel of claim 17, wherein one part of the first encapsulation layer beyond the second electrode overlaps with the third isolation portion, and the other part of the first encapsulation layer beyond the second electrode overlaps with a side wall of the second isolation portion;
the first encapsulation layer is located below the first isolation portion and is not in contact with the first isolation portion, and an orthographic projection of part of the first encapsulation layer on the array substrate is located outside the orthographic projection of the first isolation portion on the array substrate; or
the first encapsulation layer extends from the side wall of the second isolation portion to cover the first isolation portion, and a part of the first encapsulation layer overlaps with the first isolation portion and is located on a side of the first isolation portion away from the second isolation portion.

19. The display panel of claim 17, wherein in a cross section of the display panel along a thickness direction thereof, a height of the second isolation portion is in a range from 0.4 μm to 1.2 μm;
in the cross section of the display panel along the thickness direction thereof, a ratio of a length of the first isolation portion beyond the second isolation portion to the height of the second isolation portion is in a range from 1.5 to 3.0; and
in a cross section of the display panel along a thickness direction thereof, a length of the third isolation portion beyond the second isolation portion is in a range from 0.4 μm to 3.0 μm.

20. A display apparatus, comprising the display panel of claim 1.
